(19) United States
(12) Patent Application Publication
(10) Pub. No.: US 2023/0389293 A1
(43) Pub. Date: Nov. 30, 2023

(54) SEMICONDUCTOR STRUCTURE AND METHOD FOR PREPARING SAME

(71) Applicant: CHANGXIN MEMORY TECHNOLOGIES, INC., Hefei City (CN)

(72) Inventor: Min LI, Hefei (CN)

(21) Appl. No.: 17/899,684

(22) Filed: Aug. 31, 2022

Related U.S. Application Data
(63) Continuation of application No. PCT/CN2022/098124, filed on Jun. 10, 2022.

(30) Foreign Application Priority Data
May 24, 2022 (CN) 202210566896.4

(51) Int. Cl. H01L 27/108

(52) U.S. Cl. CPC H01L 27/10823; H01L 27/10814; H01L 27/10891; H01L 27/10885; H01L 27/10855

(57) ABSTRACT

A semiconductor structure and a method for preparing the same are provided. The method for preparing a semiconductor includes: providing a substrate including Active Areas (AAs) arranged in an array and an isolation structure separating the AAs, the substrate being provided with a first surface and a second surface opposite to each other; forming buried word line structures located on a side, close to the first surface, of the substrate and embedded into the AAs; forming bit line structures located on the first surface of the substrate and electrically connected to the AAs; and forming capacitor structures located on the second surface of the substrate and connected to the AAs in one-to-one correspondence.

### CROSS-REFERENCE TO RELATED APPLICATION

This is a continuation of International Patent Application No. PCT/CN2022/098124, filed on Jun. 10, 2022, which claims priority to Chinese Patent Application No. 202210566896.4, filed on May 24, 2022. The disclosures of International Patent Application No. PCT/CN2022/098124 and Chinese Patent Application No. 202210566896.4 are hereby incorporated by reference in their entireties.

### BACKGROUND

Dynamic Random Access Memory (DRAM) is a semiconductor apparatus commonly used in electronic devices such as computers, including a memory cell array for storing data, and a peripheral circuit located on the periphery of the memory cell array. Each memory cell usually includes a word line structure, a bit line structure and a capacitor. Word line voltage on the word line structure can control a transistor to turn on and turn off, so that data information stored in the capacitor can be read through the bit line structure or the data information can be written into the capacitor.

With the continuous development of a process technology, the size of the DRAM is getting smaller and smaller, and a technological node of the DRAM is 10 nm or below, which greatly increases the energy density per unit area of a DRAM device, resulting in a negative impact on device performance How to ensure that the device performance meets the requirements while continuing the trend of DRAM miniaturization is an urgent problem to be solved.

### SUMMARY

The present disclosure relates to the technical field of semiconductor preparing, and in particular to a semiconductor structure and a method for preparing same.

According to various embodiments of the disclosure, a semiconductor structure and a method for preparing the same are provided.

According to a first aspect of the present disclosure, there is provided a semiconductor structure, which includes a substrate, buried word line structures, bit line structures and capacitor structures. The substrate includes active areas arranged in an array and an isolation structure separating the active areas. The substrate has a first surface and a second surface opposite to each other. The buried word line structures are located on a side, close to the first surface, of the substrate and embedded into the active areas. The bit line structures are located on the first surface of the substrate and electrically connected to the active areas. The capacitor structures are located on the second surface of the substrate and connected to the active areas in one-to-one correspondence.

According to a second aspect of the present disclosure, there is provided a method for preparing a semiconductor structure, which includes the following operations. A substrate including active areas arranged in an array and an isolation structure separating the active areas is provided, the substrate having a first surface and a second surface opposite to each other. Buried word line structures located on a side, close to the first surface, of the substrate and embedded into the active areas are formed. Bit line structures located on the first surface of the substrate and electrically connected to the active areas are formed. Capacitor structures located on the second surface of the substrate and connected to the active areas in one-to-one correspondence are formed.

Details of one or more embodiments of the present disclosure are set forth in the following drawings and descriptions. Other features, purposes and advantages of the present disclosure will become apparent from the specification, drawings, and claims.

### BRIEF DESCRIPTION OF THE DRAWINGS

In order to describe the technical solutions in the embodiment technology of the disclosure more clearly, the drawings required to be used in descriptions about the embodiment technology will be simply introduced below. Obviously, the drawings described below are only some embodiments of the disclosure, and other drawings may further be obtained by those of ordinary skill in the art according to the drawings without creative work.

FIG. 1 is a flow block diagram of a method for preparing a semiconductor structure according to an embodiment of the disclosure.

FIG. 2 is a sectional structural diagram of a substrate according to an embodiment of the disclosure.

FIG. 3A is a sectional structural diagram of a semiconductor structure after an active area and an isolation structure are formed in a substrate according to an embodiment of the disclosure.

FIG. 3B is a sectional structural diagram taken in an aa′ direction in FIG. 3A.

FIG. 4 is a sectional structural diagram of a semiconductor structure after a first patterned mask layer is formed according to an embodiment of the disclosure.

FIG. 5 is a sectional structural diagram of a semiconductor structure after a word line trench is formed according to an embodiment of the disclosure.

FIG. 6 is a sectional structural diagram of a semiconductor structure after a word line conductive layer is formed according to an embodiment of the disclosure.

FIG. 7 is a sectional structural diagram of a semiconductor structure after a word line dielectric layer is formed according to an embodiment of the disclosure.

FIG. 8 is a plan view of a semiconductor structure after an embedded word line structure is formed according to an embodiment of the disclosure.

FIG. 9 is a sectional structural diagram of a semiconductor structure after metal silicide is formed according to an embodiment of the disclosure.

FIG. 10A is a sectional structural diagram intercepted in an aa′ direction after a word line conductive material layer is formed according to an embodiment of the disclosure.

FIG. 10B is a sectional structural diagram intercepted in a bb′ direction after a word line conductive material layer is formed according to an embodiment of the disclosure.

FIG. 11A is a plan view of a semiconductor structure after a bit line structure is formed according to an embodiment of the disclosure.

FIG. 11B is a sectional structural diagram taken in the aa′ direction in FIG. 11a.

FIG. 11C is a sectional structural diagram intercepted in a bb′ direction in FIG. 11A.

FIG. 12 is a sectional structural diagram of a semiconductor structure after a bit line dielectric layer is formed according to an embodiment of the disclosure.

FIG. 13A is a sectional structural diagram of a semiconductor structure intercepted in an aa′ direction after an insulating material layer and a metal interconnection layer are formed according to an embodiment of the disclosure.

FIG. 13B is a sectional structural diagram of a semiconductor structure intercepted in a bb′ direction after an insulating material layer and a metal interconnection layer are formed according to an embodiment of the disclosure.

FIG. 14 is a sectional structural diagram after a semiconductor structure is bonded to a supporting baseplate according to an embodiment of the disclosure.

FIG. 15 is a sectional structural diagram of a semiconductor structure after a second surface of a substrate is thinned according to an embodiment of the disclosure.

FIG. 16 is a sectional structural diagram of a semiconductor structure after a node contact structure is formed according to an embodiment of the disclosure.

FIG. 17 is a sectional structural diagram of a semiconductor structure after a capacitor structure is formed according to an embodiment of the disclosure.

FIG. 18 is a sectional structural diagram of a semiconductor structure according to an embodiment of the disclosure.

### DETAILED DESCRIPTION

In order to facilitate the understanding of the disclosure, the disclosure will be described more comprehensively below with reference to the relevant drawings. Preferred embodiments of the disclosure are given in the attached drawings. However, the disclosure may be implemented in many different forms and is not limited to the embodiments described herein. On the contrary, these embodiments are provided for the purpose of making the disclosure of the application more thorough and comprehensive.

Unless otherwise defined, all technological and scientific terms used in the present disclosure have meanings same as those usually understood by those skilled in the art of the disclosure. Terms used in the description of the present disclosure are only intended to describe the specific embodiments and not intended to limit the disclosure. The terms “and/or” as used herein include any and all combinations of one or more related listed items.

When describing the positional relationship, unless otherwise specified, when an element, such as a layer, film or substrate, is referred to as being “on” another film layer, it can be directly on the other film layer or there may be an intermediate film layer. Furthermore, when a layer is referred to as being “below” another layer, it may be directly below another layer, or there may be one or more intermediate layers. It is also to be understood that when a layer is referred to as “between” two layers, it may be the only layer between the two layers, or one or more intermediate layers may also exist.

In the case of using “including”, “having” and “containing” described herein, another component can be added unless explicit limiting terms are used, such as “only”, “consisting of”, etc. Unless mentioned to the contrary, a term in the singular form may include plural forms, and should not be understood as having a quantity of one.

With the continuous development of a process technology, the size of the DRAM is getting smaller and smaller, and a technological node of the DRAM is 10 nm or below, which greatly increases the energy density per unit area of a DRAM device, resulting in a negative impact on device performance How to ensure that the device performance meets the requirements while continuing the trend of DRAM miniaturization is an urgent problem to be solved. In order to solve the above problem, the present disclosure discloses a semiconductor structure and a method for preparing same.

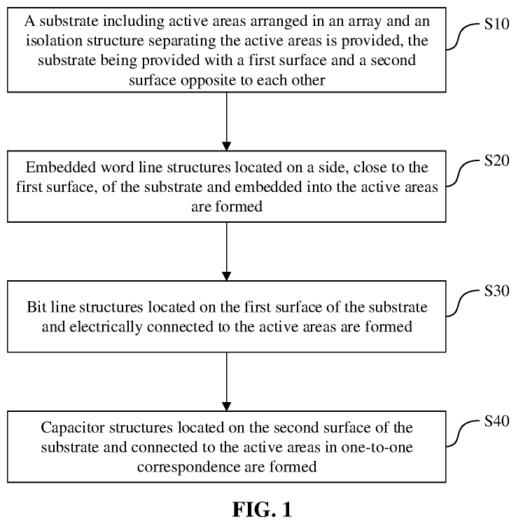

As shown in FIG. 1, one embodiment of the disclosure discloses a method for preparing a semiconductor structure according to an embodiment of the disclosure.

At S10, a substrate including Active Areas (AAs) arranged in an array and an isolation structure separating the AAs is provided, the substrate being provided with a first surface and a second surface opposite to each other.

At S20, buried word line structures located on a side, close to the first surface, of the substrate and embedded into the AAs are formed.

At S30, bit line structures located on the first surface of the substrate and electrically connected to the AAs are formed.

At S40, capacitor structures, located on the second surface of the substrate and connected to the AAs in one-to-one correspondence are formed.

According to the method for preparing the semiconductor structure, the word line structure, the bit line structure and the AA are formed on the side close to the first surface of the substrate, and the capacitor structure is formed on the side close to the second surface of the substrate, so that the transistor structure and the capacitor structure share the same-plane region, thereby reducing the cell area of a single DRAM structure and improving the storage density. Meanwhile, since the transistor structure and the capacitor structure are located on two opposite sides of the substrate without the need of occupying each other's space, the device size does not need to be miniaturized, thus ensuring that the device performance is not affected. In addition, the buried word line structure is embedded into the AA, so that the gate control ability can be enhanced and the working current can be improved.

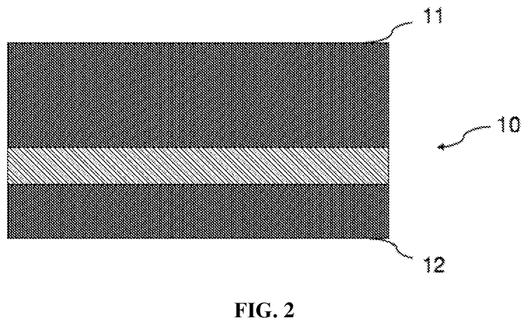

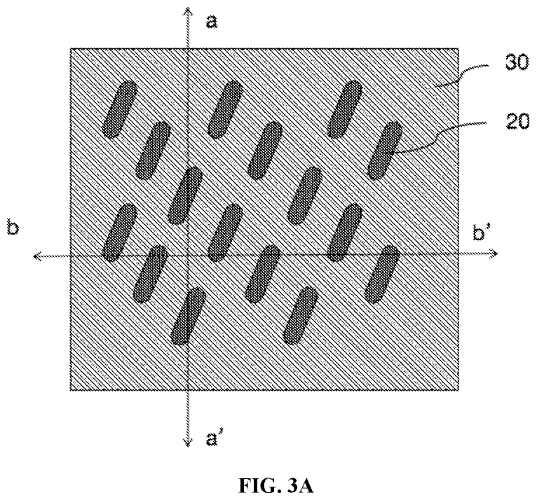

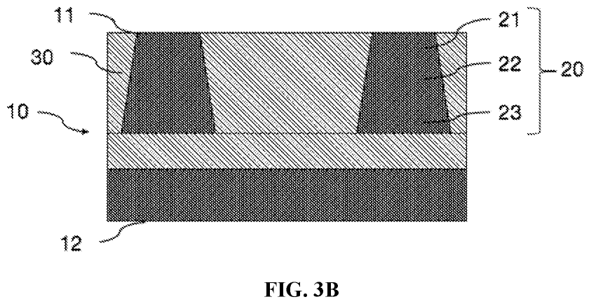

In S10, the substrate 10 may include, but is not limited to, a silicon substrate or a Silicon-on-Insulator (SOI) substrate. Exemplarily, as shown in FIG. 2, the embodiment is explained by taking the SOI substrate as an example. The SOI substrate includes top silicon, a back substrate, and a buried oxide layer between the top silicon and the back substrate. AAs 20 arranged in an array and an isolation structure 30 separating the AAs 20 are formed in the substrate 10, as shown in FIGS. 3A and 3B. Exemplarily, the isolation structure 30 may be a Shallow Trench Isolation (STI) structure 30, and the material forming the STI structure 30 may include a silicon oxide layer. The STI structure 30 defines a plurality of AAs 20 in the substrate 10, and the plurality of AAs 20 may be arranged in a staggered array.

As shown in FIG. 3A which is a top view of the substrate 10, the AAs 20 may be arranged in parallel with each other, and the center of one AA 20 may be adjacent to the end part of the other AA 20 adjacent thereto. As shown in FIG. 3B, which is a sectional structural diagram of the substrate 10 in the aa′ direction, each AA 20 includes a source terminal 21, a drain terminal 23 and a channel region 22 located between the source terminal 21 and the drain terminal 23, which are arranged in the vertical direction. Herein, the source terminal 21 is exposed to the first surface 11 of the substrate 10.

In some embodiments, the AA may be a PNP-type stack structure, the source terminal 21 and the drain terminal 23 are P-type doped, and the channel region 22 is N-type doped. Optionally, in some other embodiments, the AA is an NPN-type stack structure, the source terminal 21 and the drain terminal 23 are N-type doped, and the channel region 22 is P-type doped. As an example, the drain terminal 23, the source terminal 21 and the channel region 22 may be formed in the AA 20 by ion implantation or epitaxial doping.

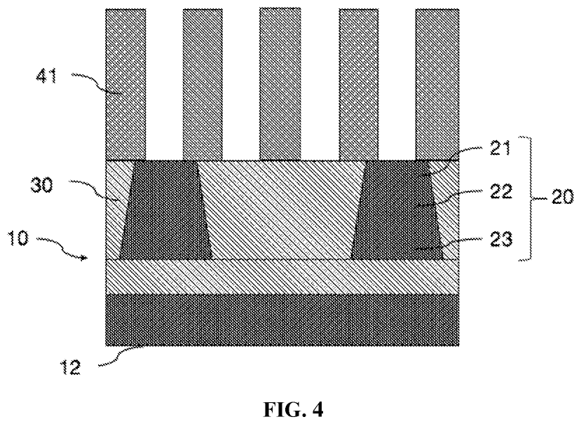

In S20, as shown in FIGS. 4-7, forming the buried word line structures 50 includes the following operations.

At S21, a first patterned mask layer 41 is formed on the first surface 11, as shown in FIG. 4.

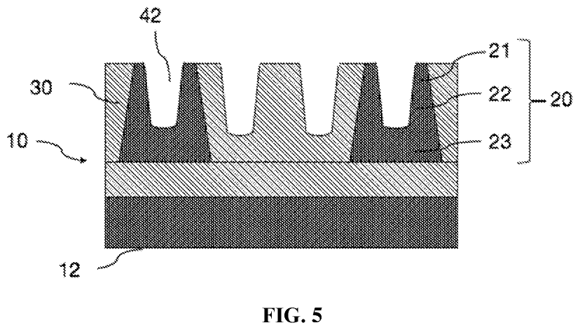

At S22, word line trenches 42 are formed in the substrate 10 based on the first patterned mask layer 41, and the word line trenches 42 extend in a first direction, as shown in FIG. 5.

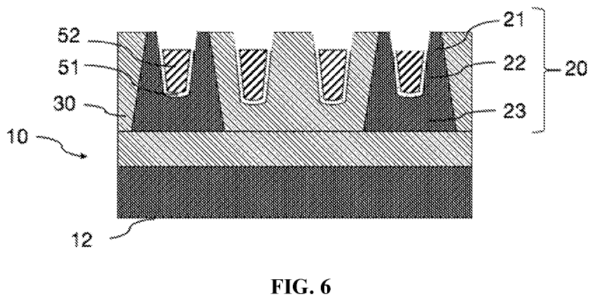

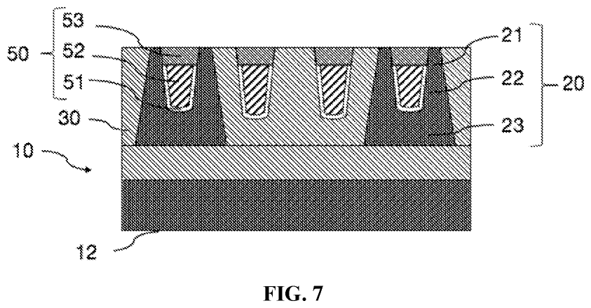

At S23, the buried word line structures 50 are formed in the word line trenches 42, as shown in FIGS. 6 and 7.

Herein, the pattern in the first patterned mask layer 41 is used to define the size and position of the word line structure. Exemplarily, the first direction is the bb′ direction shown in FIG. 3A. The word line trench 42 intersects the AA 20 in the substrate 10, and the bottom of the word line trench 42 extends to the channel region 22. Exemplarily, the bottom of the word line trench 42 is flush with the bottom of the channel region 22.

Optionally, in some embodiments, the word line trenches 42 may be formed in the substrate 10 by Self-Aligned Double Patterning (SADP) or Self-Aligned Quadruple Patterning (SAQP).

In S23, forming the buried word line structures 50 in the word line trenches 42 includes the following operations.

At S231, gate oxide layers 51 each covering a bottom and a sidewall of the word line trench 42 are formed.

At S232, word line conductive layers 52 each filling the word line trench 42 and covering the first surface 11 are formed.

At S233, the word line conductive layers 52 on the first surface 11 are removed.

At S234, a thickness of the word line conductive layer 52 in each word line trench 42 is reduced.

At S235, a word line dielectric layer 53 is formed on an upper surface of each word line conductive layer 52.

In S231, the gate oxide layer 51 may include, but is not limited to, a high dielectric constant material layer such as a silicon oxide layer or a silicon oxynitride layer. Exemplarily, the silicon oxide layer may be formed on the bottom and sidewall of the word line trench 42 by chemical vapor deposition, atomic layer deposition, plasma vapor deposition, In-Situ Steam Generation (ISSG) or Rapid Thermal Oxidation (RTO) so as to serve as the gate oxide layer 51.

In the process of forming the gate oxide layer 51, it is also easy to form a silicon oxide layer on the first surface 11 of the substrate 10, to cover the top of the AA 20, which affects the conductivity of the device. Therefore, the silicon oxide layer on the first surface 11 may be removed by Chemical Mechanical Polishing (CMP) or etching so as to expose the top of the AA 20.

In S232, exemplarily, the word line conductive layer 52 may be a metal layer 611 with low resistivity, such as Germanium (Ge), Wolfram (W), Copper (Cu) or Gold (Au). As an example, a deposition process may be employed to deposit a metal material in the word line trench 42 to form the word line conductive layer 52, and the word line conductive layer 52 fills the word line trench 42 and covers the first surface 11.

In S233 and S234, the word line conductive layer 52 on the first surface 11 may be removed by a plasma etching process, and the thickness of the word line conductive layer 52 in the word line trench 42 may be reduced, as shown in FIG. 6. Optionally, in some embodiments, after the thickness of the word line conductive layer 52 is reduced, part of the gate oxide layer 51 may be removed by a wet etching process, so that the top of the gate oxide layer 51 is lower than the first surface 11 and higher than the upper surface of the word line conductive layer 52.

Optionally, in some embodiments, the exposed gate oxide layer 51 may be etched in the horizontal direction by an anisotropic plasma etching process, and the height of the gate oxide layer 51 may be reduced so that the top of the gate oxide layer 51 is flush with the upper surface of the word line conductive layer 52. When the gate oxide layer 51 is etched by the anisotropic plasma etching process, the etching direction may be mainly concentrated in the horizontal direction, and thus the etching of the gate oxide layer 51 in the vertical direction may be minimized, so that the etched gate oxide layer 51 is flush with the upper surface of the word line conductive layer 52.

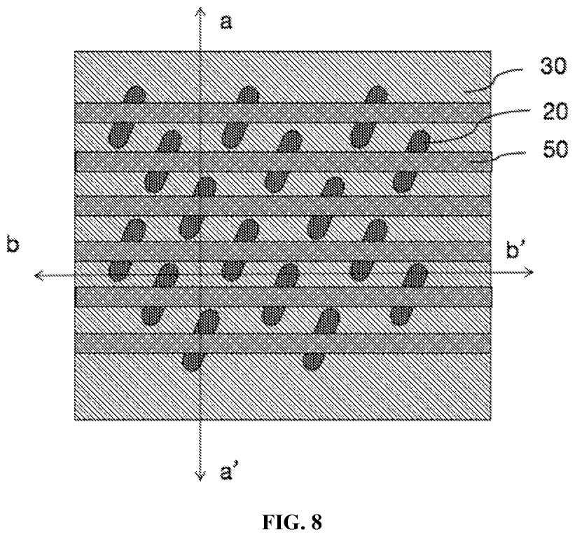

In S235, the word line dielectric layer 53 may be, for example, a silicon nitride layer. The word line dielectric layer 53 may be formed by an atomic layer deposition process or chemical vapor deposition process to cover the word line conductive layer 52 and the gate oxide layer 51. Exemplarily, the upper surface of the word line dielectric layer 53 is flush with the first surface 11, as shown in FIG. 7. After the buried word line structures 50 are formed, the top view of the obtained structure is shown in FIG. 8.

According to the method for preparing the semiconductor structure, by reducing the height of the gate oxide layer 51, it can be ensured that the word line dielectric layer 53 may cover both the word line conductive layer 52 and the gate oxide layer 51, thereby preventing the gate oxide layer 51 from being exposed to the first surface 11 to be damaged by other etching processes. In this way, the buried word line structure 50 is well protected.

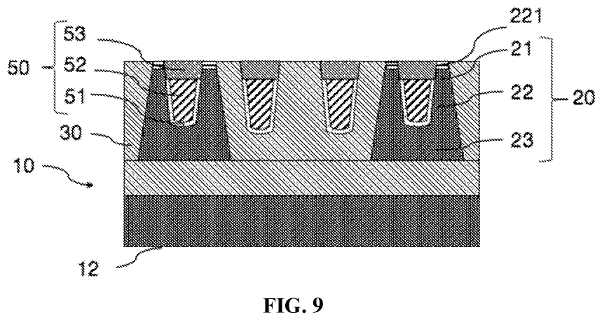

In S30, bit line structures 60 are formed on the first surface 11 of the substrate 10, and the bit line structures 60 are electrically connected to the AAs 20. Exemplarily, as shown in FIGS. 9-11C, forming the bit line structures 60 includes the following operations.

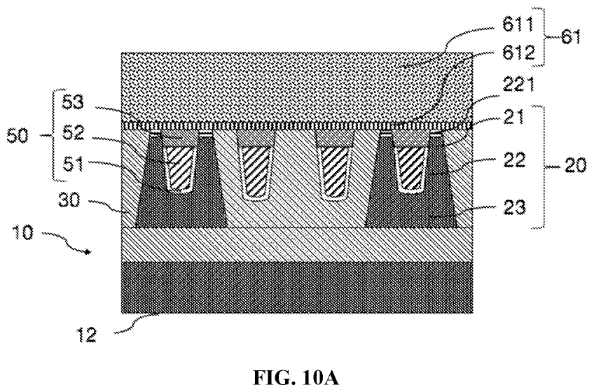

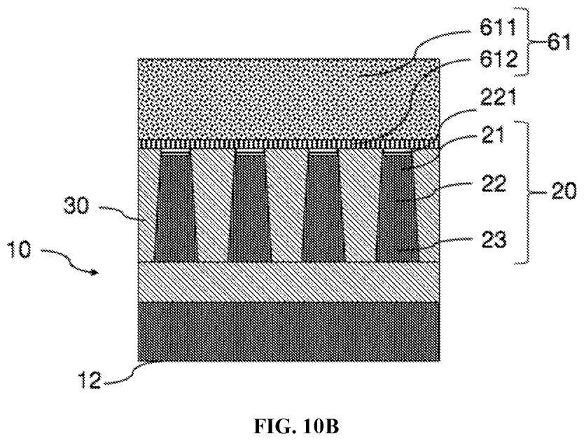

At S31, a bit line conductive material layer 61 covering the first surface 11 and the embedded word line structures 50 is formed, as shown in FIGS. 10A and 10B.

Optionally, in some embodiments, as shown in FIG. 9, before the bit line conductive material layer 61 is formed, a metal silicide 211 may also be formed on the top of each AA 20. Exemplarily, the metal silicide 211 with a first thickness is formed at the source terminal 21 so as to reduce the resistance between the source terminal 21 and the bit line structure 60 and increase the conduction current.

FIG. 10A is a sectional structural diagram taken in an aa′ direction. FIG. 10B is a sectional structural diagram taken in a bb′ direction. It can be seen from FIGS. 10A and 10B, that the bit line conductive material layer 61 covers the first surface 11 and the embedded word line structures 50, and is connected to the metal silicides 211 at the source terminals 21. Exemplarily, the bit line conductive material layer 61 includes a metal layer 611 and a metal barrier layer 612, and the metal barrier layer 612 is located between the metal layer 611 and the first surface 11. The metal layer 611 may be, for example, a wolfram layer, and the metal barrier layer 612 may be, for example, a titanium layer or a titanium nitride layer. The metal barrier layer 612 may prevent mutual permeation between the metal layer 611 and silicon.

At S32, a second patterned mask layer is formed on an upper surface of the bit line conductive material layer 61.

The second patterned mask layer includes a plurality of stripe structures extending in the second direction, the stripe structures are arranged at intervals, and the upper surface of the bit line conductive material layer 61 is exposed between adjacent stripe structures.

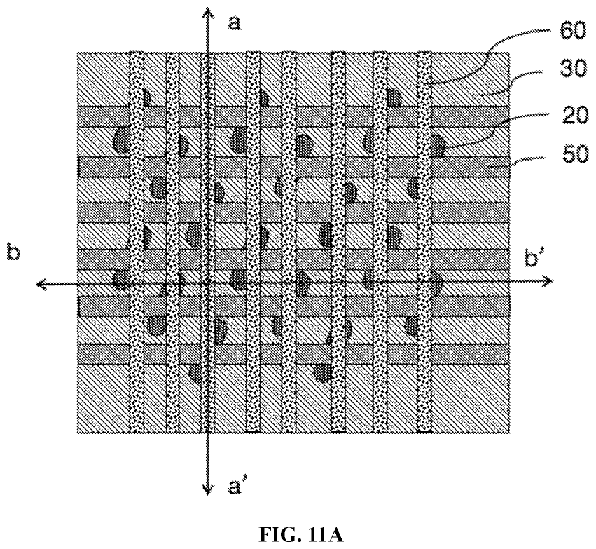

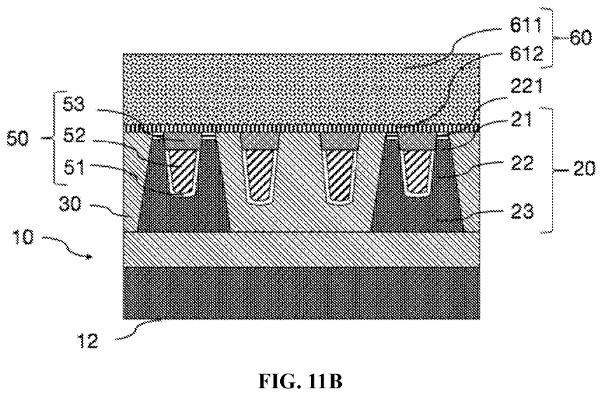

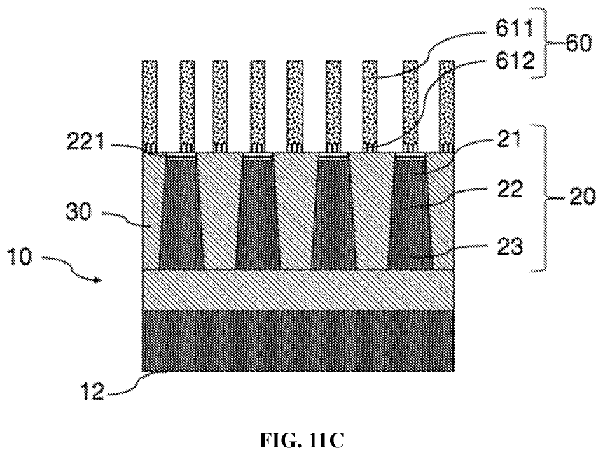

At S33, the bit line conductive material layer 61 is etched based on the second patterned mask layer until the first surface 11 is exposed to form the bit line structures 60, and the bit line structures 60 extend in the second direction, as shown in FIGS. 11A, 11B and 11C.

Herein, FIG. 11a is a top view of a semiconductor structure after the bit line structures are formed. FIG. 11B is a sectional structural diagram taken in an aa′ direction. FIG. 11C is a sectional structural diagram taken in a bb′ direction. It can be seen from FIGS. 11A to 11C that the bit line structures 60 are arranged on the first surface 11 at intervals, extend in the second direction, and are electrically connected to the source terminals 21 in the AAs 20.

In some embodiments, after the bit line structures 60 are formed, the following operations are further included.

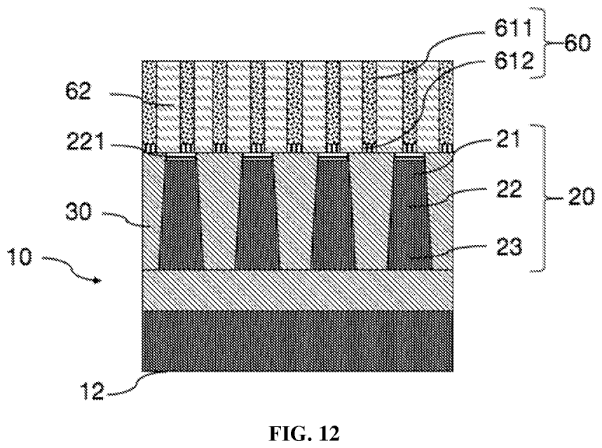

At S34, bit line dielectric layers 62 each filling a gap between the bit line structures 60 is formed, and a top surface of each of the bit line dielectric layers 62 is flush with a top surface of each of the bit line structures 60, as shown in FIG. 12.

Exemplarily, the bit line dielectric layer 62 may include, but is not limited to, a silicon nitride layer, a carbon layer, a silicon oxide layer or a silicon oxynitride layer. Exemplarily, the silicon nitride layer may be first formed in the gap between the bit line structures 60 by an atomic layer deposition process or a chemical vapor deposition process, and the silicon nitride layer fully fills the gap between the bit line structures 60 and covers the upper surfaces of the bit line structures 60. Then, the silicon nitride layer is etched by a chemical mechanical polishing process until the top surface of the bit line structure 60 is exposed, thereby forming a bit line dielectric layer 62 flush with the top surface of the bit line structure 60.

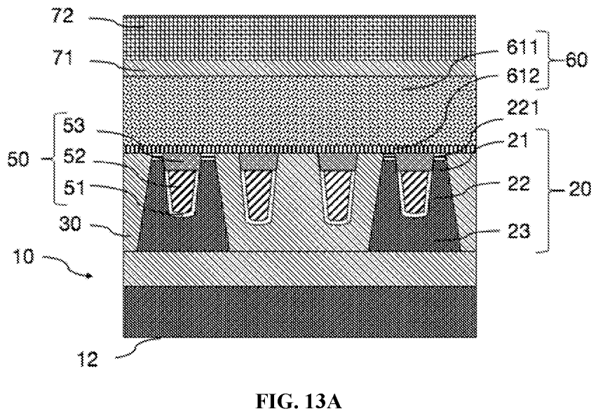

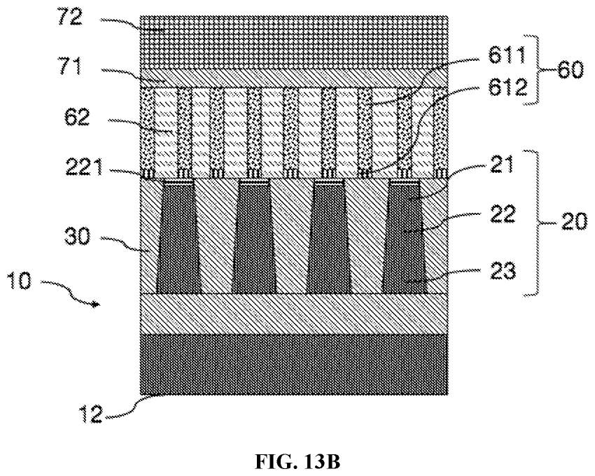

In some embodiments, as shown in FIGS. 13A-15, after the bit line dielectric layer 62 is formed, the following operations are further included.

At S35, an insulating material layer 71 covering the surfaces of the bit line structures 60 and the bit line dielectric layers 62 is formed.

At S36, a metal interconnection layer 72 is formed on a surface of the insulating material layer 71, as shown in FIGS. 13A and 13B.

Exemplarily, the insulating material layer 71 may be a silicon nitride layer and the metal interconnection layer 72 may be a copper layer. FIG. 13A is a sectional structural diagram taken in an aa′ direction. FIG. 13B is a sectional structural diagram taken in a bb′ direction. It can be seen from FIGS. 13A and 13B, the insulating material layer 71 covers the upper surfaces of the bit line structures 60 and the bit line dielectric layers 62, and the metal interconnection layer 72 covers the upper surface of the insulating material layer 71. Herein, the insulating material layer 71 and the bit line dielectric layers 62 jointly enclose and cover a bit line structure 60, thus playing a role in protecting the bit line structure 60 and preventing the bit line structure 60 from being electrically connected to the metal interconnection layer 72.

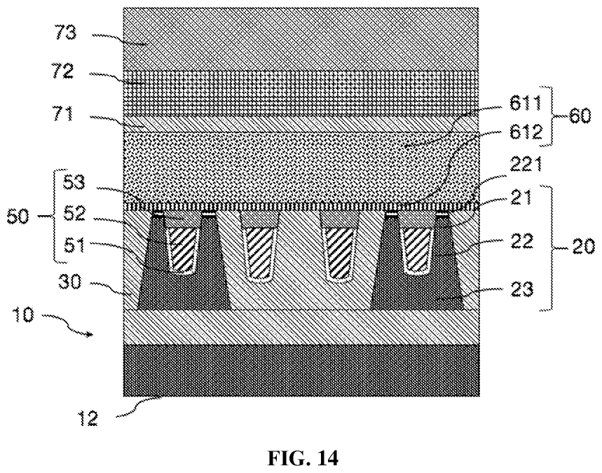

At S37, the obtained structure is bonded to a supporting baseplate 73, a surface, away from the substrate 10, of the metal interconnection layer 72 being a bonding surface, as shown in FIG. 14.

By bonding the obtained structure to the supporting baseplate 73, the obtained structure may be fixed to the supporting baseplate 73, which facilitates the subsequent thinning process and capacitor preparation process.

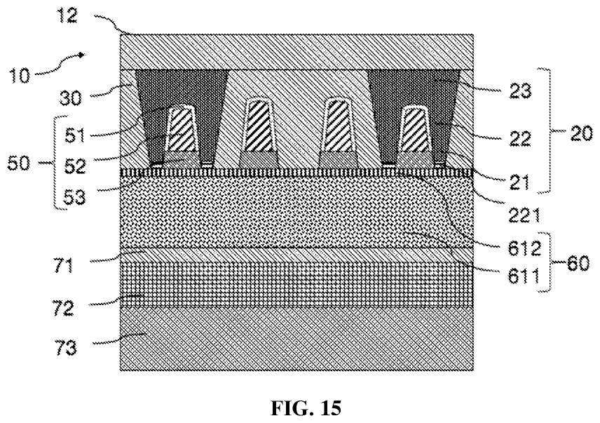

At S38, the second surface 12 of the substrate 10 is thinned, as shown in FIG. 15.

Exemplarily, the second surface 12 may be polished by CMP until the buried oxide layer in the SOI substrate is exposed, so that the node contact structure 80 can be prepared in the buried oxide layer in a subsequent process.

Optionally, in some embodiments, when the substrate 10 is a silicon substrate, the second surface 12 of the substrate 10 does not need to be thinned, and the capacitor structures 90 connected to the AAs in one-to-one correspondence may be directly formed on the second surface 12.

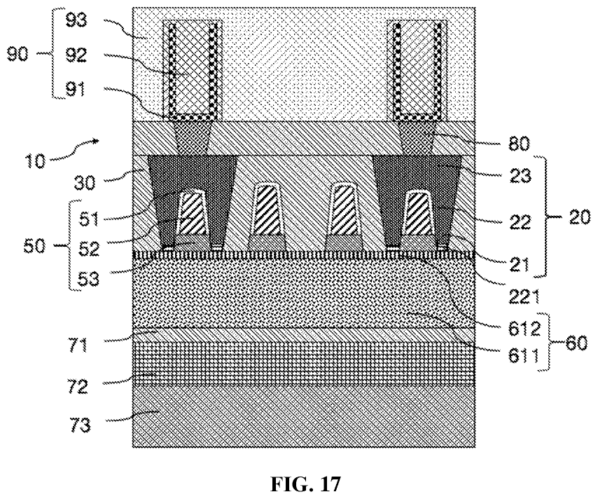

In S40, the capacitor structures 90 are formed on the second surface 12 of the substrate 10, and the capacitor structures 90 are connected to the AAs 20 in one-to-one correspondence, as shown in FIG. 17.

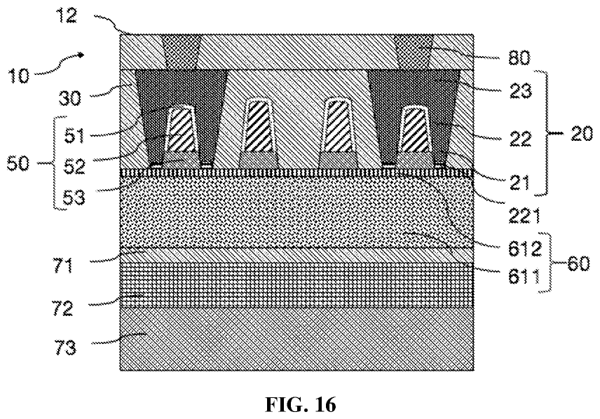

In some embodiments, before the capacitor structures 90 are formed, the following operation is further included. Node contact structures 80 are formed on a side, close to the second surface 12, of the substrate 10, and the node contact structures 80 are connected to the AAs 20 in one-to-one correspondence, as shown in FIG. 16. Herein, the node contact structure 80 penetrates through the buried oxide layer in the SOI substrate. One end of the node contact structure 80 is electrically connected to the drain terminal 23 in the AA 20, and the other end of the node contact structure is exposed to the second surface 12. Exemplarily, the node contact structure 80 may include, but is not limited to, a wolfram layer.

Exemplarily, forming the capacitor structures 90 includes the following operations.

At S41, a plurality of capacitor structures 90 arranged in an array are formed on the second surface 12, and the capacitor structure 90 includes a lower electrode 91, an upper electrode 93 and a capacitor dielectric layer 92 located between the lower electrode 91 and the upper electrode 93. Herein, the lower electrode 91 as shown is electrically connected to the node contact structure 80.

As shown in FIG. 17, the capacitor structures 90 are electrically connected to the drain terminals 23 of the AAs 20 through the node contact structures 80, and the capacitor structures 90 is connected to the AAs 20 in one-to-one correspondence.

According to the method for preparing the semiconductor structure, the word line structure, the bit line structure and the AA are formed on the side close to the first surface of the substrate, and the capacitor structure is formed on the side close to the second surface of the substrate, so that the transistor structure and the capacitor structure share the same-plane region, thereby reducing the area of a single DRAM unit. Meanwhile, since the transistor structure and the capacitor structure do not need to occupy each other's space, the device size does not need to be miniaturized, thus ensuring that the device performance is not affected. In addition, the buried word line structure is embedded into the AA, so that the gate control ability can be enhanced and the working current can be increased.

As an example, by adopting the method for preparing the semiconductor structure in the above embodiment, a DRAM device with a cell area of 4F² may be prepared. Compared with a traditional DRAM device structure, the DRAM device has smaller cell area, so the storage density is higher.

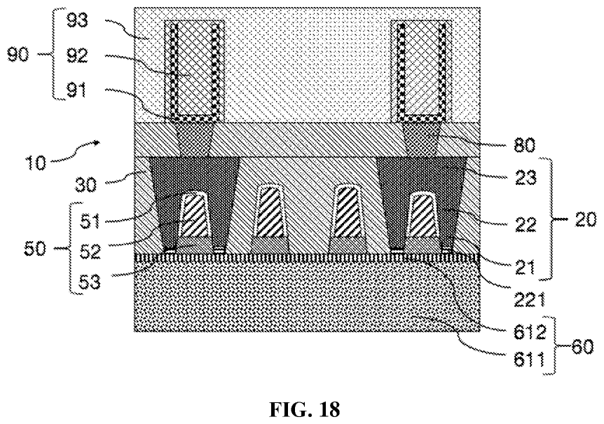

Another aspect of the disclosure further provides a semiconductor structure. As shown in FIG. 18, the semiconductor structure includes: a substrate 10, buried word line structures 50, bit line structures 60 and capacitor structures 90. The substrate includes AAs 20 arranged in an array and an isolation structure 30 separating the AAs 20. The substrate 10 is provided with a first surface 11 and a second surface 12 opposite to each other. The buried word line structures 50 are located on a side, close to the first surface 11, of the substrate 10 and embedded into the AAs 20. The bit line structures 60 are located on the first surface 11 of the substrate 10 and electrically connected to the AAs 20. The capacitor structures 90 are located on the second surface 12 of the substrate 10 and connected to the AAs 20 in one-to-one correspondence.

In the semiconductor structure, the buried word line structure 50, the bit line structure 60 and the AA 20 are located on the side, close to the first surface 11, of the substrate 10, and the capacitor structure 90 is located on the side, close to the second surface 12, of the substrate 10, so that the transistor structure and the capacitor structure 90 share the same region, thereby reducing the area occupied by a single DRAM unit and improving the storage density. Meanwhile, since the transistor structure and the capacitor structure 90 do not need to occupy each other's space, the device size does not need to be miniaturized, thus ensuring that the device performance is not affected. In addition, since the buried word line structure 50 is embedded into the AA, the gate control ability can be enhanced and the working current can be increased.

Exemplarily, the substrate 10 may include, but is not limited to, a silicon substrate or an SOI substrate. The isolation structure 30 may be an STI structure 30, and the material forming the STI structure 30 may include a silicon oxide layer. The STI structure 30 defines a plurality of AAs 20 in the substrate 10. As shown in FIG. 3A which is a top view of the substrate 10, the plurality of AAs 20 may be arranged in a staggered array, the AAs 20 are arranged in parallel with each other, and the center of one AA 20 may be adjacent to the end part of the other AA 20 adjacent thereto.

Each AA 20 includes a source terminal 21, a drain terminal 23 and a channel region 22 located between the source terminal 21 and the drain terminal 23, which are arranged in the vertical direction. The channel region 22 is perpendicular to the first surface 11 or the second surface 12, and the source terminal 21 and the drain terminal 23 are not on a same plane. Exemplarily, the source terminal 21 is exposed to the first surface 11 of the substrate 10 and electrically connected to the bit line structure 60. The drain terminal 23 is located on a side, facing away from the first surface 11, of the substrate 10, and is electrically connected to the capacitor structure 90. Exemplarily, the AA may be a PNP-type stack structure. Herein, the source terminal 21 and the drain terminal 23 are P-type doped, and the channel region 22 is N-type doped. Optionally, in some other embodiments, the AA is an NPN-type stack structure. Herein, the source terminal 21 and the drain terminal 23 are N-type doped, and the channel region 22 is P-type doped.

The bit line structure 60 is located on the first surface 11 of the substrate 10. Exemplarily, the bit line structure 60 may include a metal layer 611 and a metal barrier layer 612, and the metal barrier layer 612 is located between the metal layer 611 and the first surface 11. The metal layer 611 may be, for example, a wolfram layer, and the metal barrier layer 612 may be, for example, a titanium layer or a titanium nitride layer. The metal barrier layer 612 may prevent mutual penetration between the metal layer 611 and silicon. As shown in FIG. 18, a bit line dielectric layer 62 is further arranged between adjacent bit line structures 60, so as to completely separate bit line structures 60. Exemplarily, the bit line dielectric layer 62 may include, but is not limited to, a silicon nitride layer, a carbon layer, a silicon oxide layer or a silicon oxynitride layer.

In some embodiments, as shown in FIG. 18, the buried word line structure 50 on a side, away from the first surface 11 has a word line conductive layer 52 embedded into the channel region 22 in the AA 20. The buried word line structure 50 also includes a gate oxide layer 51 located between the word line conductive layer 52 and the AA 20.

Exemplarily, the gate oxide layer 51 may include, but is not limited to, a high dielectric constant material layer such as a silicon oxide layer or a silicon oxynitride layer. The word line conductive layer 52 may be a metal layer 611 with low resistivity, such as Germanium (Ge), Wolfram (W), Copper (Cu) or Gold (Au).

Herein, the word line conductive layer 52 is embedded into the AA 20 and extends to the channel region 22, so that two current channels may be formed in the AA 20. As shown in FIG. 18, the two current channels are respectively located on the two sides of the buried word line structure 50, so that the conduction current of the transistor and the gate control capability are increased.

In some embodiments, continuously referring to FIG. 18, the buried word line structure 50 on a side close to the first surface 11 has a word line dielectric layer 53 located in the substrate 10, and a surface, close to the first surface 11, of the word line dielectric layer 53 is flush with the first surface 11 and exposed to the first surface 11 of the substrate 10.

The word line dielectric layer 53 covers the word line conductive layer 52 and the gate oxide layer 51 in the substrate 10, to have a good protection effect on the word line conductive layer 52 and the gate oxide layer 51, and to improve the performance stability of the device.

In some embodiments, as shown in FIG. 18, the semiconductor structure further includes node contact structures 80 located on a side, close to the second surface 12, of the substrate 10, and a surface, close to the second surface 12, of the node contact structure 80 is flush with the second surface 12 and exposed to the second surface 12 of the substrate 10. The capacitor structure 90 is electrically connected to the drain terminal 23 of the AA 20 through the node contact structure 80.

Exemplarily, the material for forming the node contact structure 80 may include, but is not limited to, a wolfram layer. The node contact structure 80 penetrates through the buried oxide layer in the SOI substrate. One end of the node contact structure 80 is electrically connected to the drain terminal 23 in the AA 20, and the other end of the node contact structure is exposed to the second surface 12 and electrically connected to the capacitor structure 90.

Exemplarily, the capacitor structure 90 include a lower electrode 91, an upper electrode 93 and a capacitor dielectric layer 92 located between the lower electrode 91 and the upper electrode 93. Herein, the lower electrode 91 is electrically connected to the node contact structure 80. The capacitor structure 90 is electrically connected to the drain terminal 23 of the AA 20 through the node contact structure 80.

One embodiment of the present disclosure further discloses a semiconductor device, which includes the semiconductor structure in any of the above embodiments. Exemplarily, the above semiconductor device may be a DRAM device, and the cell area of the DRAM device is 4F². Compared with a traditional DRAM device structure, the semiconductor device has higher storage density and conduction current.

It is to be understood that although the steps in the flowcharts of FIG. 1 are shown in sequence as indicated by the arrows, these steps are not necessarily executed in sequence as indicated by the arrows. Unless explicitly stated herein, the execution of these steps is not strictly limited in sequence, and these steps may be executed in other sequences. Furthermore, at least a part of the steps in FIG. 1 may include multiple steps or multiple stages. These sub-steps or stages may not necessarily be completed at the same time, but may be executed at different times. These steps or stages may not necessarily be performed sequentially, but may be executed in turn or alternately with other steps or at least a part of steps or stages of other steps.

In the delay circuit and semiconductor memory provided by the embodiments of the present disclosure, the word line structure, the bit line structure and the active area are located on the side of the first surface of the substrate, and the capacitor structure is located on the side of the second surface of the substrate, so that the transistor structure and the capacitor structure can be formed in the same region, thereby reducing the area of a single DRAM unit. Meanwhile, since the transistor structure and the capacitor structure do not need to occupy each other's space, the device size does not need to be miniaturized, thus ensuring that the device performance is not affected. In addition, since the buried word line structure is embedded into the active area, the gate control ability can be enhanced and the working current can be increased. By embedding the word line conductive layer into the channel region in the active area, two current channels may be formed in the channel region, which are respectively located on the two opposite sides of the word line structure, so that the working current of the device may be increased and the gate control capability may be enhanced. The word line dielectric layer may cover the gate oxide layer and the word line conductive layer in the substrate, which has a good protection effect on the word line conductive layer and the gate oxide layer, thereby improving the performance stability of the device.

In conclusion, the delay circuit and the semiconductor memory provided by the embodiments of the present disclosure enable DRAM devices to meet the performance requirements while reducing the size.

All the technical characteristics of the above embodiments may be combined arbitrarily. In order to make the descriptions concise, not all possible combinations of the technical characteristics in the above embodiments have been described. However, as long as there is no contradiction among the combinations of these technical characteristics, they shall be considered as the scope recorded in the specification.

The above embodiments only express several implementation manners of the disclosure, and their descriptions are more specific and detailed, but they cannot be understood as limiting the scope of the disclosure. It is to be pointed out that, for those of ordinary skill in the art, without departing from the concept of the disclosure, several modifications and improvements may also be made, which all fall within the scope of protection of the disclosure. Therefore, the scope of protection of the disclosure shall be subject to the appended claims.

1. A semiconductor structure, comprising:
a substrate, comprising active areas arranged in an array and an isolation structure separating the active areas, the substrate having a first surface and a second surface opposite to each other;
buried word line structures, located on a side, close to the first surface, of the substrate and embedded into the active areas;
bit line structures, located on the first surface of the substrate and electrically connected to the active areas; and
capacitor structures, located on the second surface of the substrate and connected to the active areas in one-to-one correspondence.

2. The semiconductor structure of claim 1, wherein each of the active areas comprises a source terminal, a drain terminal and a channel region located between the source terminal and the drain terminal, and
the bit line structure is connected to the source terminal of the active area, and the capacitor structure is connected to the drain terminal of the active area.

3. The semiconductor structure of claim 2, wherein the buried word line structure on a side away from the first surface has a word line conductive layer embedded into the channel region in the active area,
wherein the buried word line structure further comprises a gate oxide layer located between the word line conductive layer and the active area.

4. The semiconductor structure of claim 2, wherein the source terminal and the drain terminal are not on a same plane.

5. The semiconductor structure of claim 2, wherein the channel region is perpendicular to the first surface or the second surface.

6. The semiconductor structure of claim 2, wherein the source terminal and the drain terminal are P-doped, and the channel region is N-doped, or
the source terminal and the drain terminal are N-doped, and the channel region is P-doped.

7. The semiconductor structure of claim 3, wherein the buried word line structure on a side, close to the first surface has a word line dielectric layer located in the substrate, a surface, close to the first surface, of the word line dielectric layer being flush with the first surface and exposed to the first surface of the substrate.

8. The semiconductor structure of claim 2, further comprising node contact structures located on a side, close to the second surface, of the substrate, wherein a surface, close to the second surface, of each of the node contact structures is flush with the second surface and exposed to the second surface of the substrate,
the capacitor structure is electrically connected to the drain terminal of the active area through the node contact structure.

9. A method for preparing a semiconductor structure, comprising:
providing a substrate comprising active areas arranged in an array and an isolation structure separating the active areas, the substrate having a first surface and a second surface opposite to each other;
forming buried word line structures located on a side, close to the first surface, of the substrate and embedded into the active areas;
forming bit line structures located on the first surface of the substrate and electrically connected to the active areas; and
forming capacitor structures located on the second surface of the substrate and connected to the active areas in one-to-one correspondence.

10. The method for preparing the semiconductor structure of claim 9, wherein forming the buried word line structures comprises:
forming a first patterned mask layer on the first surface;
forming word line trenches in the substrate based on the first patterned mask layer, wherein the word line trenches extend in a first direction; and
forming the buried word line structures in the word line trenches.

11. The method for preparing the semiconductor structure of claim 10, wherein forming the buried word line structures in the word line trenches comprises:
forming gate oxide layers each covering a bottom and a sidewall of the word line trench;
forming word line conductive layers each filling the word line trench and covering the first surface;
removing the word line conductive layers on the first surface;
reducing a thickness of the word line conductive layer in each word line trench; and
forming a word line dielectric layer on an upper surface of each word line conductive layer.

12. The method for preparing the semiconductor structure of claim 9, wherein forming the bit line structures comprises:
forming a bit line conductive material layer covering the first surface and the buried word line structures;
forming a second patterned mask layer on an upper surface of the bit line conductive material layer; and
etching the bit line conductive material layer based on the second patterned mask layer until the first surface is exposed to form the bit line structures, wherein the bit line structures extend in a second direction.

13. The method for preparing the semiconductor structure of claim 12, wherein the bit line conductive material layer comprises: a metal layer and a metal barrier layer located between the metal layer and the first surface.

14. The method for preparing the semiconductor structure of claim 12, after forming the bit line structures, further comprising:
forming bit line dielectric layers each filling a gap between the bit line structures, a top surface of each of the bit line dielectric layers being flush with a top surface of each of the bit line structures.

15. The method for preparing the semiconductor structure of claim 14, after forming the bit line dielectric layers, further comprising:
forming an insulating material layer covering the surfaces of the bit line structures and the bit line dielectric layers;
forming a metal interconnection layer on a surface of the insulating material layer;
bonding the obtained structure to a supporting baseplate, wherein a surface, away from the substrate, of the metal interconnection layer is a bonding surface; and
thinning the second surface of the substrate.

16. The method for preparing the semiconductor structure of claim 15, before forming the capacitor structures, further comprising:
forming node contact structures on a side, close to the second surface, of the substrate, wherein the node contact structures are connected to the active areas in one-to-one correspondence.

17. The method for preparing the semiconductor structure of claim 16, wherein forming the capacitor structures comprises:
forming a plurality of capacitor structures arranged in an array on the second surface, wherein the capacitor structure comprise a lower electrode, an upper electrode and a capacitor dielectric layer located between the lower electrode and the upper electrode, the lower electrode being electrically connected to the node contact structure.

18. The method for preparing the semiconductor structure of claim 9, wherein a drain terminal, a source terminal and a channel region are formed in the active area by ion implantation or epitaxial doping.

19. The method for preparing the semiconductor structure of claim 9, wherein the substrate comprises a silicon-on-insulator substrate.
